(19) United States
(12) Patent Application Publication
(10) Pub. No.: US 2012/0154131 A1
(43) Pub. Date: Jun. 21, 2012

(54) APPARATUS AND METHOD FOR TRANSMITTING FORCE VECTOR

(75) Inventors: Hyung Kew Lee, Gunpo-si (KR); Joon Ah Park, Seoul (KR)

(73) Assignee: SAMSUNG ELECTRONICS CO., LTD, Suwon-si (KR)

(21) Appl. No.: 13/306,773

(22) Filed: Nov. 29, 2011

(30) Foreign Application Priority Data
Dec. 21, 2010 (KR) 10-2010-0131339

(51) Int. Cl. G08B 6/00; G05G 1/00; B23P 11/00; H01L 41/09

(52) U.S. Cl. 340/407.1; 310/328; 74/469; 29/428

(57) ABSTRACT

A force vector transferring apparatus to transfer a force vector to a finger of a human being. The force vector transferring apparatus may include an outer wall being formed of a hard material, an inner wall being formed of a flexible material to surround an inserted object, and an actuator being disposed between the inner wall and the outer wall to transfer a force to the object through the inner wall. The force vector transferring apparatus may transfer, to an end portion of a finger of a human being, a force from a plurality of directions acting on an end portion of a robot finger.

### CROSS-REFERENCE TO RELATED APPLICATIONS

This application claims the priority benefit of Korean Patent Application No. 10-2010-0131339, filed on Dec. 21, 2010, in the Korean Intellectual Property Office, the disclosure of which is incorporated herein by reference.

### BACKGROUND

1. Field

Example embodiments of the following description relate to an apparatus and method for transferring a force vector to a human, and more particularly, to an apparatus and method, including actuators to transfer force from a plurality of directions to an object inserted into the apparatus.

2. Description of the Related Art

To remotely manipulate a robot, or to intuitively manipulate an object within a virtual space, there is a need to artificially generate a sense substantially perceived at a hand or an arm of a user when manipulating an object, and to transfer the generated sense to the user.

### SUMMARY

The foregoing and/or other aspects are achieved by providing an apparatus for transferring a force vector, including an inner wall being expanded by an inserted object; an outer wall surrounding the inner wall; and an actuator being disposed between the inner wall and the outer wall to transfer a force to the object through the inner wall.

The foregoing and/or other aspects are achieved by providing an apparatus for transferring a force vector, including an outer wall including an inner space to be inserted with an object; and a plurality of actuators being disposed within the outer wall to transfer, to the object, a force from a plurality of directions acting on the outer wall.

The foregoing and/or other aspects are achieved by providing an apparatus for transferring a force vector, including an outer wall including an opening to be inserted with an end portion of a finger; and an actuator being disposed within the outer wall to transfer a force to the end portion of the finger.

According to example embodiments, it is possible to transfer, to an end portion of a finger of a human being, a force from a plurality of directions acting on an end portion of a robot finger.

According to example embodiments, since an end portion of a robot manipulating a sensitive tissue or object, such as an operation robot, is enabled to transfer, to a manipulator, a force in contact with the tissue, it is possible to enhance the efficiency and the stability of a task using the robot.

According to example embodiments, it is possible to enhance a sensitivity of a tactile sense by transferring a force to a finger through an inner wall formed as a protrusion.

According to example embodiments, since fluid is supplied to an actuator at a predetermined pressure and is expanded by the pressure of the supplied fluid, it is possible to directly transfer a magnitude of the force to a finger.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects will become apparent and more readily appreciated from the following description of embodiments, taken in conjunction with the accompanying drawings of which:

FIG. 1 illustrates an example of a plurality of forces acting on a robot finger;

FIG. 2 illustrates a perspective view of a force vector transferring apparatus according to example embodiments;

FIG. 3 illustrates an actuator included in a force vector transferring apparatus according to example embodiments;

FIG. 4 illustrates a cross-sectional view of the force vector transferring apparatus cut based on B of FIG. 2 according to example embodiments;

FIG. 5 illustrates a cross-sectional view of the force vector transferring apparatus cut based on A of FIG. 2 according to example embodiments; and

FIG. 6 illustrates a method of transferring a force vector according to example embodiments.

### DETAILED DESCRIPTION

Reference will now be made in detail to embodiments, examples of which are illustrated in the accompanying drawings, wherein like reference numerals refer to the like elements throughout. Embodiments are described below to explain the present disclosure by referring to the figures.

To remotely manipulate a robot, or to intuitively manipulate an object within a virtual space, there is a need to artificially generate a sense substantially perceived at a hand or an arm of a user when manipulating an object, and to transfer the generated sense to the user.

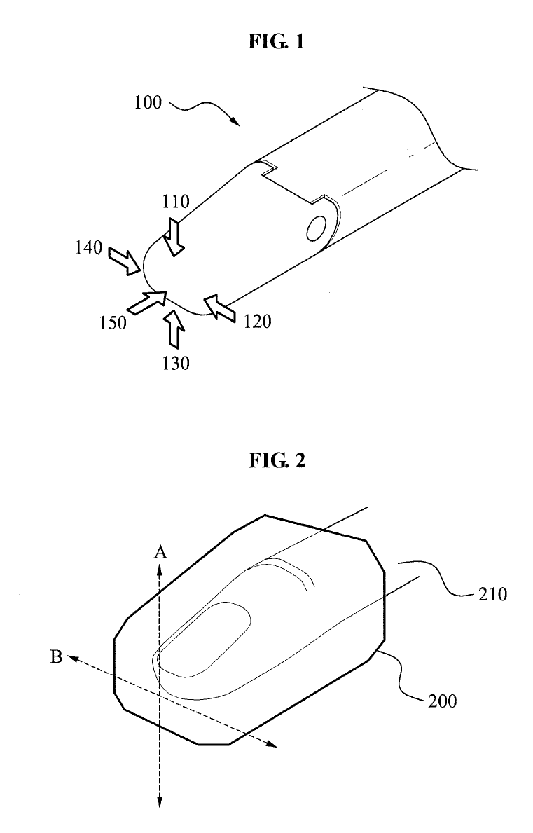

FIG. 1 illustrates an example of a plurality of forces acting on a robot finger 100.

Referring to FIG. 1, when a robot manipulates an object, a force from a plurality of directions may act on an end portion of a robot finger 100. For example, the plurality of directions may include a front direction 150, an up direction 110, a down direction 130, a left direction 140, and a right direction 120.

FIG. 2 illustrates a force vector transferring apparatus 200 according to example embodiments.

Referring to FIG. 2, the force vector transferring apparatus 200 may include an inner wall to be inserted with an object 210 and thereby be expanded by the inserted object 210, a hard outer wall to surround the inner wall in a thimble shape, and an actuator being disposed between the inner wall and the outer wall to transfer a force to the object 210 through the inner wall. The object 210 may be, for example, a finger of a human being.

The force vector transferring apparatus 200 may be attached to an end portion of a finger of a human being and thereby be used. The force vector transferring apparatus 200 may be provided in a thimble shape to transfer the force from the plurality of forces as shown in FIG. 1.

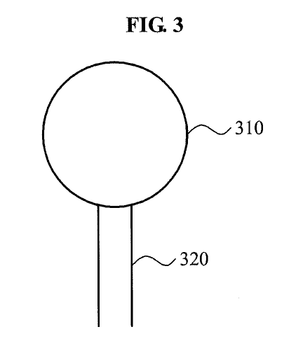

FIG. 3 illustrates an actuator 310 included in a force vector transferring apparatus 200 according to example embodiments.

Referring to FIG. 3, the actuator 310 may transfer, to an object, a force from each of a plurality of forces as shown in FIG. 1. The actuator 310 may have an expansion and contraction enabling structure. For example, the actuator 310 may be provided in a pocket structure such as a balloon formed of a flexible rubber material and containing a fluid. The expansion and the contraction of the balloon may be controlled, by a controlling module, based on an amount of fluids supplied to the balloon. A conduit 320 may be provided to supply the fluid. For example, when a fluid such as air is injected into the conduit 320 at a predetermined pressure, the balloon may be expanded by the pressure. When a deflation is performed, the balloon may be contracted.

According to an embodiment, a plurality of actuators may be provided to the force vector transferring apparatus 200 to correspond to at least one of a plurality of directions, for example, the front direction 150, the up direction 110, the down direction 130, the left direction 140, and the right direction 120 of FIG. 1. For example, five actuators may be provided to correspond to the front direction 150, the up direction 110, the down direction 130, the left direction 140, and the right direction 120.

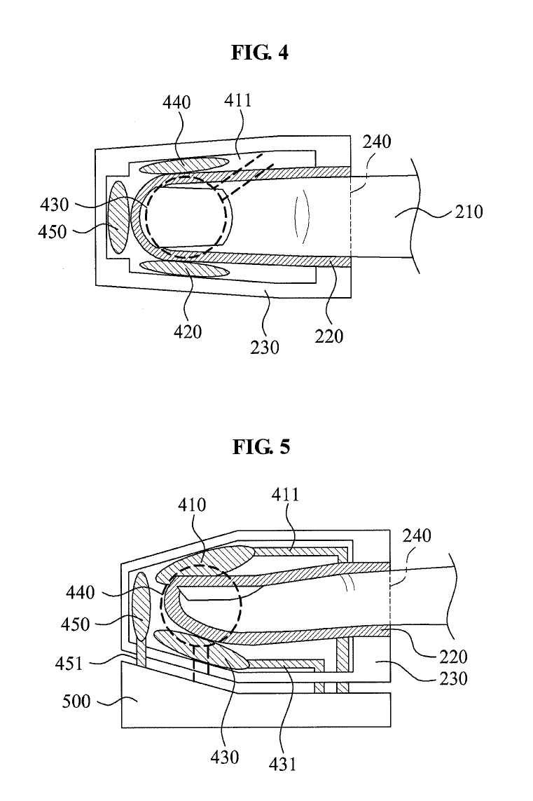

FIG. 4 illustrates a cross-sectional view of the force vector transferring apparatus 200 cut based on B of FIG. 2.

Referring to FIG. 4, the force vector transferring apparatus 200 may include an outer wall 230, an inner wall 220 to surround the object 210, and a plurality of actuators 410, 420, 430, 440, and 450.

The outer wall 230 may have a thimble shape and be formed of a hardened material. An opening 240 may be formed in the outer wall 230, and may have a size enabling the object 210, for example, an end portion of a finger of a human being, to be inserted. An inner space connected to the opening 240 may be formed to have a size sufficient to receive the end portion of the finger. As described above, the opening 240 may correspond to a space surrounded by the inner wall 220. The outer wall 230 may be provided in the thimble shape in order to be more effectively attached to the object 210, for example, the finger of the human being.

The inner wall 220 may be expanded by the inserted object 210. The inner wall 220 may make direct contact with the object 210 and thus, may be formed of a flexible material so that the force vector transferring apparatus 200 may be closely attached to the object 210.

The plurality of actuators 410, 420, 430, 440, and 450 may be disposed between the inner wall 210 and the outer wall 230 to transfer the force to the object 210 through the inner wall 220. For example, five actuators 410, 420, 430, 440, and 450 may be provided to correspond to the front direction 150, the up direction 110, the down direction 130, the left direction 140, and the right direction 120 of FIG. 1.

For example, the actuator 430 corresponding to a force from the down direction 130 of the robot finger 100 may be disposed below the finger of the human being. A conduit 431 supplying a fluid to the actuator 430 may be connected below the force vector transferring apparatus 200 through an empty space formed between the inner wall 220 and the outer wall 230. The actuator 450 corresponding to the force from the front direction 150 of the robot finger 100 may be disposed in front of the finger of the human being. A conduit 451 of FIG. 5 supplying a fluid to the actuator 450 may be connected below the force vector transferring apparatus 200 through an empty space formed between the inner wall 220 and the outer wall 230.

FIG. 5 illustrates a cross-sectional view of the force vector transferring apparatus 200 cut based on A of FIG. 2.

A basic configuration will be described with reference to FIG. 5.

Conduits 411 through 451 corresponding to the actuators 410, 420, 430, 440, and 450, respectively, may be connected to a control module 500 controlling a fluid through a bottom surface of the force vector transferring apparatus 200.

When the object 210 is inserted into the inner wall 220 of the force vector transferring apparatus 200, the inner wall 220 may make direct or close contact with the object 210. The control module 500 may supply the fluid to the actuators 410, 420, 430, 440, and 450 through each of the respective conduits 411 through 451 in charge of corresponding directions. When the fluid is supplied to the actuators 410, 420, 430, 440, and 450, the pressure may be applied to the actuators 410, 420, 430, 440, and 450, whereby the actuators 410, 420, 430, 440, and 450 may transfer a force from corresponding directions to corresponding portions of the object 210.

Depending on embodiments, the force vector transferring apparatus 200 may be provided to correspond to various sizes and shapes of a finger occurring due to the flexibility of the inner wall 200 and the actuators 410, 420, 430, 440, and 450.

When a protrusion is formed in a portion where the object 210 makes direct contact with the inner wall 220 of the force vector transferring apparatus 200, it is possible to enhance the sensitivity of tactile sense of the object 210, for example, the finger.

In addition to a balloon typed actuator, it is possible to employ an actuator using an electro active polymer (EAP) or a piezoelectric element with respect to the actuators 410, 420, 430, 440, and 450.

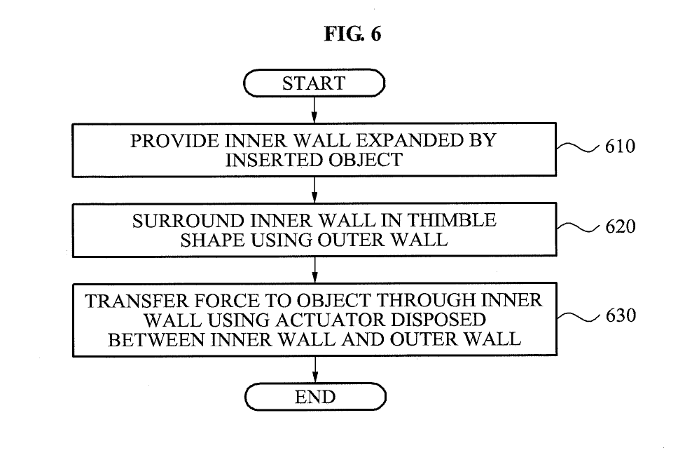

FIG. 6 illustrates a method of transferring a force vector according to example embodiments.

In operation 610, the force vector transferring apparatus 200 may provide the inner wall 220 expanded by the inserted object 210. The inner wall 220 corresponds to a portion making direct contact with the object 210 and thus, may be formed of a flexible material so that the force vector transferring apparatus 200 may be closely attached to the object 210.

In operation 620, the force vector transferring apparatus 200 may surround the inner wall 220 using the outer wall 230 formed of a hardened material.

In operation 630, the force vector transferring apparatus 200 may transfer the force to the object 210 using the actuators 410 through 450 that are disposed between the inner wall 220 and the outer wall 230. As described, the actuators 410 through 450 may be provided to correspond to the front direction 150, the up direction 110, the down direction 130, the left direction 140, and the right direction 120, respectively.

For example, when the object 210 is a finger of a human being, and when the object 210 is inserted into the inner wall 220 of the force vector transferring apparatus 200, the inner wall 220 may make direct or close contact with the finger. The control module 500 may supply the fluid to the actuators 410, 420, 430, 440, and 450 through the conduits 411 through 451 in charge of corresponding directions. When the fluid is supplied to the actuators 410, 420, 430, 440, and 450, the pressure may be applied to the actuators 410, 420, 430, 440, and 450, whereby the actuators 410, 420, 430, 440, and 450 may transfer a force from corresponding directions to corresponding portions.

By forming a protrusion in a portion where the object 210 makes direct or close contact with the inner wall 220 of the force vector transferring apparatus 200, it is possible to enhance the sensitivity of tactile sense of the object 210, for example, the finger.

Methods and apparatuses according to example embodiments may be embodied using various types of packages. For example, the methods and apparatuses may be embodied using packages such as Package on Packages (PoPs), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Quad Flatpack (QFP), Small Outline Integrated Circuit (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

The embodiments can be implemented in computing hardware (computing apparatus) and/or software, such as (in a non-limiting example) any computer that can store, retrieve, process and/or output data and/or communicate with other computers. The results produced can be displayed on a display of the computing hardware. A program/software implementing the embodiments may be recorded on non-transitory computer-readable media comprising computer-readable recording media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW.

Further, according to an aspect of the embodiments, any combinations of the described features, functions and/or operations can be provided.

Although embodiments have been shown and described, it would be appreciated by those skilled in the art that changes may be made in these embodiments without departing from the principles and spirit of the disclosure, the scope of which is defined by the claims and their equivalents.

What is claimed is:

1. An apparatus for transferring a force vector, comprising:
an inner wall expanded by an inserted object;
an outer wall surrounding the inner wall; and
an actuator being disposed between the inner wall and the outer wall to transfer a force to the object through the inner wall.

2. The apparatus of claim 1, wherein the actuator has an expansion and contraction enabling structure.

3. The apparatus of claim 2, wherein the actuator comprises a balloon formed of a rubber material.

4. The apparatus of claim 3, wherein the actuator further comprises a conduit to supply a fluid to the balloon.

5. The apparatus of claim 4, wherein the actuator further comprises a control module being disposed on a bottom surface of the force vector transferring apparatus to control the fluid supplied to the conduit.

6. The apparatus of claim 1, further comprising a plurality of actuators is provided to transfer, to the object, a force from a plurality of directions.

7. The apparatus of claim 1, wherein the actuator comprises an electro active polymer (EAP) or a piezoelectric element.

8. The apparatus of claim 1, wherein the inner wall comprises a protrusion.

9. An apparatus for transferring a force vector, comprising:
an outer wall comprising an inner space to be inserted with an object; and
a plurality of actuators disposed within the outer wall to transfer, to the object, a force from a plurality of directions.

10. The apparatus of claim 9, wherein each of the actuators comprises an electro active polymer (EAP) or a piezoelectric element.

11. The apparatus of claim 9, wherein each of the actuators is expanded based on a magnitude of a force transferred from each of different directions.

12. The apparatus of claim 9, wherein each of the actuators is supplied with a fluid at a predetermined pressure through a conduit to transfer the force using the pressure of the supplied fluid.

13. The apparatus of claim 12, wherein the plurality of actuators further comprise a control module being disposed on a bottom surface of the force vector transferring apparatus to control the fluid supplied to the conduit.

14. An apparatus for transferring a force vector, comprising:
an outer wall comprising an opening to be inserted with an end portion of a finger; and
an actuator disposed within the outer wall to transfer a force to the end portion of the finger.

15. The apparatus of claim 14, wherein a plurality of actuators is provided.

16. The apparatus of claim 15, wherein at least five actuators are provided.

17. The apparatus of claim 15, wherein the plurality of actuators transfers the force from different directions, respectively.

18. The apparatus of claim 17, wherein the different directions comprise an up direction, a down direction, a left direction, a right direction, and a front direction based on the end portion of the finger.

19. The apparatus of claim 14, further comprising:
an inner wall to directly transfer, to the end portion of the finger, a magnitude of the force transferred via the actuator.

20. The apparatus of claim 19, wherein the inner wall is expanded based on the magnitude of the force, and stimulates a tactile sense of the end portion of the finger using a portion formed as a protrusion.

21. The apparatus of claim 17, wherein the actuator further comprises a control module being disposed on a bottom surface of the force vector transferring apparatus to control the fluid supplied to the actuators.

22. A method of transferring a force vector, comprising:
providing an inner wall expanded by an inserted object;
surrounding the inner wall using an outer wall; and
transferring a force to the inserted object through the inner wall using a plurality of actuators.

23. The method of claim 22, wherein the transferring force further comprises extracting or contracting the actuators.

24. The method of claim 23, wherein the transferring force further comprises controlling the fluid supplied to the actuators, using a controlling module.
